(19) United States
(12) Patent Application Publication
(10) Pub. No.: US 2026/0239647 A1
(43) Pub. Date: Aug. 13, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Mi Seong PARK, Icheon-si Gyeonggi-do (KR); Na Yeong YANG, Icheon-si Gyeonggi-do (KR); Jung Shik JANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 19/311,880

(22) Filed: Aug. 27, 2025

(30) Foreign Application Priority Data
Feb. 13, 2025 (KR) 10-2025-0018738

(51) Int. Cl. H10D 30/01; H10B 43/10; H10B 43/27; H10B 43/35; H10D 30/69

(52) U.S. Cl. CPC H10D 30/0413; H10B 43/10; H10B 43/27; H10B 43/35; H10D 30/693

(57) ABSTRACT

A method of manufacturing a memory device includes forming a channel opening extending through a stack in a first direction, forming, in the channel opening, a first data storage pattern spaced apart from a second data storage pattern in a second direction perpendicular to the first direction, forming a channel layer inside the first data storage pattern and the second data storage patterns, forming, inside the channel layer, a first barrier pattern spaced apart from a second barrier pattern in the second direction, and forming a first channel pattern spaced apart from a second channel pattern spaced apart in the second direction by removing a segment of the channel layer between the first barrier pattern and the second barrier pattern.

### CROSS REFERENCE TO RELATED APPLICATION

The present application claims priority under 35 U.S.C. §119(a) to Korean patent application number 10-2025-0018738 filed on Feb. 13, 2025, in the Korean Intellectual Property Office, the entire contents of which application is incorporated herein by reference.

### BACKGROUND

### 1. Technical Field

The present disclosure relates to a memory device and a method of manufacturing the memory device, including but not limited to a memory device including a memory block having a three-dimensional structure and a method of manufacturing the memory block.

### 2. Related Art

A memory device may include a non-volatile memory device that retains stored data when the power supply is interrupted. The non-volatile memory device has a two-dimensional structure or a three-dimensional structure, depending on the structure in which memory cells are arranged. Memory cells of a non-volatile memory device having a two-dimensional structure are arranged in a single layer on a substrate. Memory cells of a non-volatile memory device having a three-dimensional structure are stacked vertically on the substrate. Because the integration density of a non-volatile memory device having a three-dimensional structure is higher than the integration density of a non-volatile memory device having a two-dimensional structure, electronic devices have recently increased use of non-volatile memory devices having a three-dimensional structure.

### SUMMARY

According to an embodiment, a method of manufacturing a memory device may include forming a channel opening extending through a stack in a first direction, forming, in the channel opening, a first data storage pattern spaced apart from a second data storage pattern in a second direction perpendicular to the first direction, forming a channel layer inside the first data storage pattern and the second data storage pattern, forming, inside the channel layer, a first barrier pattern spaced apart from a second barrier pattern in the second direction, and forming a first channel pattern spaced apart from a second channel pattern in the second direction by removing a segment of the channel layer between the first barrier pattern and the second barrier pattern.

According to an embodiment, a memory device may include a stack including a cell plug disposed in a channel opening extending through the stack in a first direction, within the cell plug, a first data storage pattern spaced apart from a second data storage pattern in a second direction perpendicular to the first direction, within the cell plug, a first channel pattern spaced apart from a second channel pattern in the second direction, and, within the cell plug, a first tunneling pattern located between the first data storage pattern and the first channel pattern, and a second tunneling pattern located between the second data storage pattern and the second channel pattern; wherein ends of the first data storage pattern extend beyond corresponding ends of the first channel pattern in the second direction, and ends of the first data storage pattern do not extend beyond corresponding ends of the first tunneling pattern in the second direction.

According to an embodiment, a memory device may include a stack including a cell plug disposed in a channel opening extending through the stack in a first direction, within the cell plug, a first data storage pattern spaced apart from a second data storage pattern in a second direction perpendicular to the first direction, within the cell plug, a first channel pattern spaced apart from a second channel pattern in the second direction, and, within the cell plug, a tunneling layer extending between the first data storage pattern and the first channel pattern and between the second data storage pattern and the second channel pattern; wherein the tunneling layer includes a first angled region located at an end of the first data storage pattern and a second angled region located at an end the second data storage pattern.

### BRIEF DESCRIPTION OF THE DRAWINGS

FIG. 1 is a diagram illustrating a memory device according to an embodiment of the present disclosure;

FIG. 2 is a diagram illustrating a memory device according to an embodiment of the present disclosure;

FIG. 3 is a circuit diagram illustrating a connection configuration of a memory block according to an embodiment of the present disclosure;

FIGS. 4A and 4B are diagrams illustrating the structure of a memory device according to an embodiment of the present disclosure;

FIG. 5 is a plan view illustrating the structure of a memory device according to an embodiment of the present disclosure;

FIGS. 6A to 6H are diagrams illustrating a memory device formed utilizing a method of manufacturing the memory device according to an embodiment of the present disclosure;

FIG. 7 is a plan view illustrating the structure of a memory device according to an embodiment of the present disclosure;

FIGS. 8A to 8H are diagrams illustrating a memory device formed utilizing a method of manufacturing the memory device according to an embodiment of the present disclosure;

FIGS. 9A to 9E are diagrams illustrating a memory device formed utilizing a method of manufacturing the memory device according to an embodiment of the present disclosure;

FIG. 10 is a diagram illustrating a memory card system according to an embodiment of the present disclosure; and

FIG. 11 is a diagram illustrating a solid state drive (SSD) system including a memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “vertical,” “top,” “above,” “overlap,” “on,” “side,” “lower,” “higher,” “column,” “row,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas. The drawings are not necessarily drawn to scale, and complete versions of some structures are not shown between the cross-sectional views and corresponding plan views.

When one element is identified as “coupled” to another element, the elements may be coupled directly or through at least one intervening element between the elements. When two elements are identified as “directly coupled,” one element is directly coupled to the other element without an intervening element between the two elements.

Terms such as “first” and “second” are used to distinguish between various components and do not imply size, order, priority, quantity, or importance of the components. For example, a first component may be referred to as a second component in one example, and the second component may be referred to as a first component in another example.

To improve the integration of non-volatile memory devices with three-dimensional structures, a memory device according to an embodiment includes two or more cell strings formed in a single channel opening.

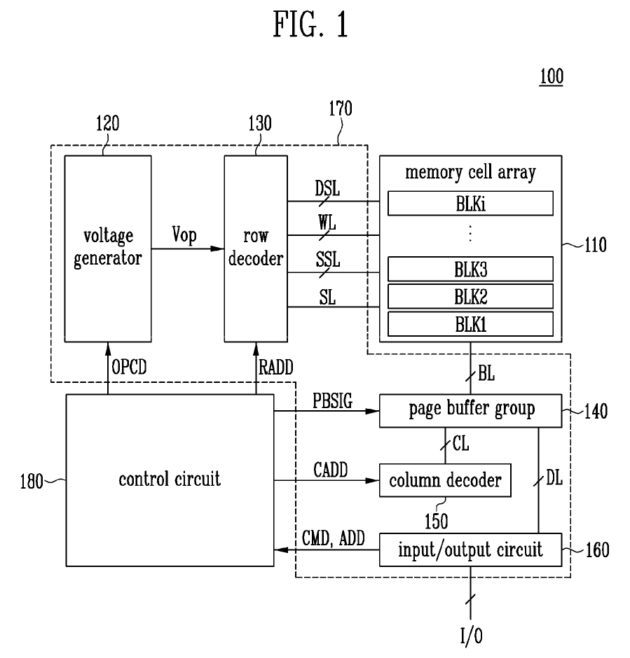

FIG. 1 is a diagram illustrating a memory device 100 according to an embodiment of the present disclosure.

Referring to FIG. 1, the memory device 100 includes a memory cell array 110, a peripheral circuit 170, and a control circuit 180.

The memory cell array 110 may include first to ith memory block BLK1 to BLKi, where i is an integer greater than 1. Each of the first to ith memory blocks BLK1 to BLKi includes memory cells that store data. Drain select lines DSL, word lines WL, source select lines SSL, and a source line SL are coupled to each of the memory blocks BLK1 to BLKi. Bit lines BL are coupled in common to the memory blocks BLK1 to BLKi.

The memory blocks BLK1 to BLKi have a three-dimensional structure. Memory blocks having a three-dimensional structure include memory cells stacked vertically on the substrate. The memory cells may be arranged in various ways in the memory blocks BLK1 to BLKi. For example, two or more cell strings may be disposed in a single channel opening extending through a stack. When two or more cell strings are disposed in a single channel opening, the integration density of the memory cells is increased compared to when one cell string is disposed in a single channel opening.

Memory cells store one bit or two or more bits of data, depending on how the memory cells are programmed. For example, a single memory cell that stores one bit of data is referred to as a single level cell, and a single memory cell that stores two bits of data is referred to as a multi-level cell. A single memory cell that stores three bits of data is referred to as a triple level cell, and a single memory cell that stores four bits of data is referred to as a quad level cell. Five or more bits of data may be stored in a single memory cell.

The peripheral circuit 170 performs a program operation to store data in the memory cell array 110, a read operation to output data stored in the memory cell array 110, and an erase operation to erase data stored in the memory cell array 110. For example, the peripheral circuit 170 includes a voltage generator 120, a row decoder 130, a page buffer group 140, a column decoder 150, and an input/output circuit 160.

The voltage generator 120 generates various operating voltages Vop that are used during a program operation, a read operation, or an erase operation in response to an operation code OPCD. For example, the voltage generator 120 generates program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 are applied to the drain select lines DSL, the word lines WL, the source select lines SSL, and the source line SL of the selected memory block via the row decoder 130.

Program voltages are applied to a selected word line of the word lines WL during a program operation and are used to increase threshold voltages of the memory cells coupled to the selected word line. Turn-on voltages are applied to the drain select lines DSL and the source select lines SSL and turn on drain select transistors and source select transistors. Turn-off voltages are applied to the drain select lines DSL and the source select lines SSL and turn off the drain select transistors and the source select transistors. For example, the turn-off voltage may be 0 V. Precharge voltages are higher than 0 V and are applied to bit lines during a read operation. Verify voltages are used during a verify operation to determine when the threshold voltage of the selected memory cells reaches a target level. The verify voltages are at various levels depending on the target level and are applied to selected word lines.

Read voltages are applied to a selected word line during a read operation of the selected memory cells. For example, the read voltages are at various levels depending on how the selected memory cells are programmed. Pass voltages may be applied to unselected word lines of the word lines WL during a program or read operation and are used to turn on memory cells coupled to unselected word lines. Erase voltages are used to erase memory cells included in selected memory blocks during an erase operation and are applied to the source line SL.

The row decoder 130 transfers, according to a row address RADD, the operating voltages Vop to the drain select lines DSL, the word lines WL, the source select lines SSL, and the source line SL coupled to a selected memory block. For example, the row decoder 130 is coupled to the voltage generator 120 through global lines and is coupled to the memory blocks BLK1 to BLKi using the drain select lines DSL, the word lines WL, the source select lines SSL, and the source line SL.

The page buffer group 140 includes page buffers (not shown) coupled to the first to ith memory blocks BLK1 to BLKi, respectively. Each of the page buffers is coupled to one of the memory blocks BLK1 to BLKi via bit lines BL. During a read operation, the page buffers sense a current or a voltage on the bit lines that varies according to the threshold voltages of the selected memory cells in response to page buffer control signals PBSIG and temporarily stores the sensed data.

The column decoder 150 transfers data between the page buffer group 140 and the input/output circuit 160 in response to a column address CADD. For example, the column decoder 150 is coupled to the page buffer group 140 through column lines CL and transfers enable signals via the column lines CL. The page buffers included in the page buffer group 140 receive or output data via data lines DL in response to the enable signals.

The input/output circuit 160 receives or outputs a command CMD, an address ADD, or data through input/output lines I/O. For example, the input/output circuit 160 transfers the command CMD and the address ADD received from an external controller to the control circuit 180 via the input/output lines I/O and transfers data received from the external controller to the page buffer group 140 via the input/output lines I/O. Alternatively, the input/output circuit 160 output data received from the page buffer group 140 to the external controller via the input/output lines I/O.

In response to the command CMD and the address ADD, the control circuit 180 outputs at least one of the operation code OPCD, the row address RADD, the page buffer control signals PBSIG, and the column address CADD. For example, when the command CMD input to the control circuit 180 corresponds to a program operation, the control circuit 180 controls the peripheral circuit 170 to perform the program operation on the memory block selected by the address ADD. When the command CMD input to the control circuit 180 corresponds to a read operation, the control circuit 180 controls the peripheral circuit 170 to perform the read operation on the memory block selected by the address ADD and output the read data. When the command CMD input to the control circuit 180 corresponds to an erase operation, the control circuit 180 controls the peripheral circuit 170 to perform the erase operation on the selected memory block.

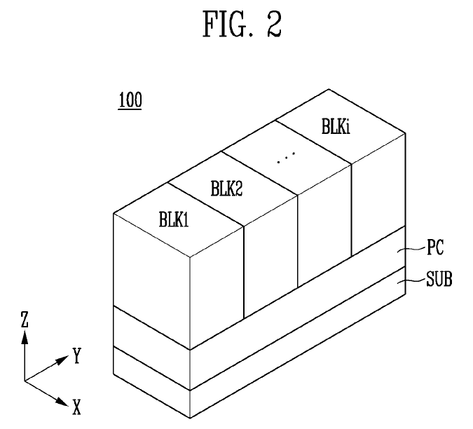

FIG. 2 is a diagram illustrating the memory device 100 according to an embodiment of the present disclosure.

Referring to FIG. 2, the memory device 100 includes a peripheral circuit structure PC arranged on a substrate SUB and the first memory block BLK1 to the ith memory block BLKi. The memory blocks BLK1 to BLKi are disposed over the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin layer formed by selective epitaxial growth.

The peripheral circuit structure PC includes the row decoder 130, the column decoder 150, the page buffer group 140, and the control circuit 180 that include circuitry that controls the operations of the memory blocks BLK1 to BLKi. For example, the peripheral circuit structure PC may include NMOS transistors, PMOS transistors, resistors, and capacitors electrically coupled to the first to ith memory blocks BLK1 to BLKi. The peripheral circuit structure PC may be arranged between the substrate SUB and the memory blocks BLK1 to BLKi.

Each of the memory blocks BLK1 to BLKi includes a source structure, bit lines, cell strings electrically coupled to the source structure and the bit lines, word lines electrically coupled to the cell strings, and select lines electrically coupled to the cell strings. Each of the cell strings includes memory cells and select transistors coupled in series. Each of the select lines is a gate electrode of a corresponding select transistor, and each of the word lines is a gate electrode of a corresponding memory cell.

In an embodiment, the substrate SUB, the peripheral circuit structure PC, and the memory blocks BLK1 to BLKi are stacked in a different order than the order shown in FIG. 2. For example, the peripheral circuit structure PC may be arranged on top of the memory blocks BLK1 to BLKi.

In an alternative embodiment, the peripheral circuit structure PC is arranged on regions of the substrate SUB that do not overlap the memory blocks BLK1 to BLKi. For example, the peripheral circuit structure PC and the memory blocks BLK1 to BLKi may be located in different regions of the substrate SUB that do not vertically overlap with each other.

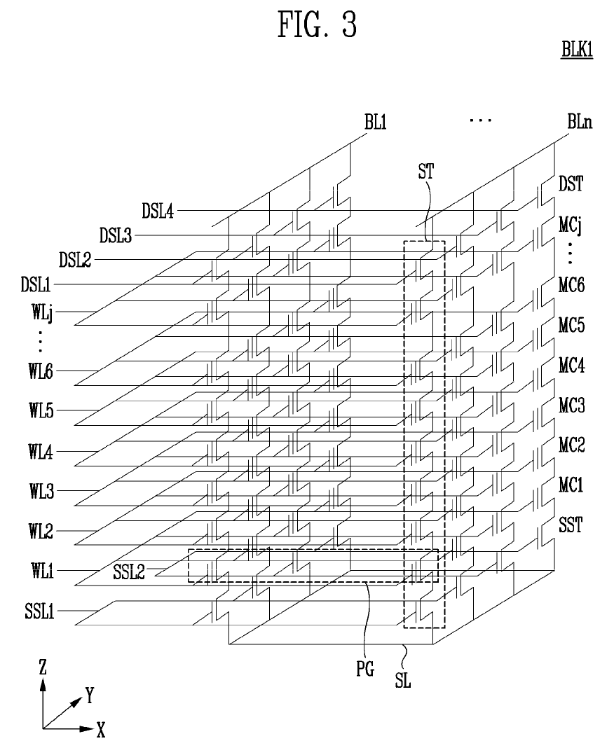

FIG. 3 is a circuit diagram illustrating a connection configuration of a memory block according to an embodiment of the present disclosure.

FIG. 3 is a diagram illustrating configurations included in the first memory block BLK1, for example. FIG. 3 illustrates at least some of the configurations included in the first memory block BLK1. The second memory block BLK2 to the ith memory block BLKi include configurations similar to the configurations shown of the first memory block BLK1 shown in FIG. 3.

Referring to FIG. 3, the first memory block BLK1 includes cell strings ST coupled between the source line SL and a first bit line BL1 to an nth bit line BLn. Because the bit lines BL1 to BLn extend in a Y direction and are spaced apart in an X direction, the cell strings ST are spaced apart in the X direction and the Y direction. For example, the cell strings ST are coupled between the first bit line BL1 and the source line SL, and the cell strings ST are arranged between the second bit line BL2 and the source line SL. Similarly, the cell strings ST are arranged between the nth bit line BLn and the source line SL. The cell strings ST extend in a Z direction.

Describing one of the cell strings ST coupled to the nth bit line BLn as an example, the cell string ST includes a source select transistor SST, a first memory cell MC1 to a jth memory cell MCj, and a drain select transistor DST, where j is an integer greater than 1. The structure of the memory block is described based on the first memory block BLK1 as shown in FIG. 3. The quantity of source select transistors SST, memory cells MC1 to MCj, and drain select transistors DST included in the cell strings ST varies depending on the memory device.

Gates of the source select transistors SST in the different cell strings are coupled to a first source select line SSL1 or a second source select line SSL2. The gates of the memory cells MC1 to MCj are coupled to the word lines WL1 to WLj, respectively. Each of the gates of the drain select transistors DST are coupled to one of the first drain select line DSL1 to the fourth drain select line DSL4.

Lines coupled to the first memory block BLK1 are described. The source select transistors SST arranged in the X direction are coupled to the same source select line, and the source select transistors SST arranged in the Y direction are coupled to source select lines that are separates. For example, a first set of the source select transistors SST arranged in the Y direction is coupled to the first source select line SSL1 and a second set of the select transistors SST is coupled to the second source select line SSL2. The second source select line SSL2 is separated from the first source select line SSL1. Therefore, a voltage applied to the first source select line SSL1 is the same voltage as or a different voltage from a voltage applied to the second source select line SSL2.

Among the memory cells MC1 to MCj, memory cells formed in the same layer are coupled to the same word line. For example, the first memory cell MC1 included in different cell strings ST is coupled in common to the first word line WL1, and the jth memory cell MCj included in the different cell string ST is coupled in common to the jth word line WLj. A group of memory cells included in different cell strings ST and coupled to the same word line is a page PG. Program and read operations may be performed on a page PG basis.

The drain select transistors DST arranged in the Y direction are coupled to the drain select lines DSL1 to DSL4 that are separated. The drain select transistors DST arranged in the X direction is coupled to the same drain select line, and the drain select transistors DST arranged in the Y direction are coupled to the drain select lines DSL1 to DSL4 that are separated. Because the drain select lines DSL1 to DSL4 are isolated from each other, different voltages may be applied to the drain select lines DSL1 to DSL4.

According to the present disclosure, two or more cell strings ST may be disposed in each of the channel openings that extend through the stack. A structure and a manufacturing method of a memory device having two cell strings ST located in one channel opening are described.

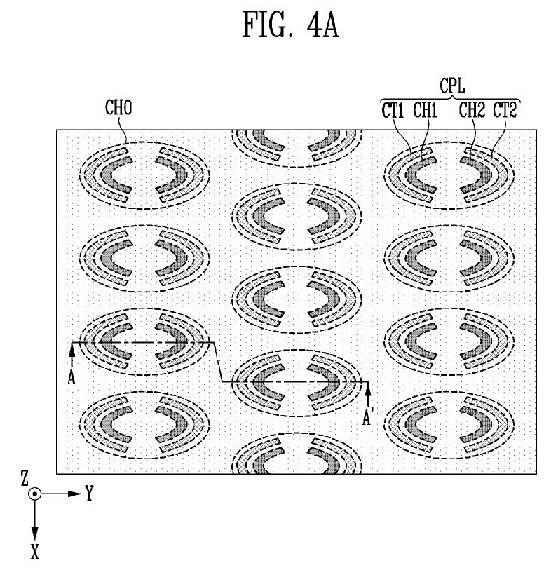

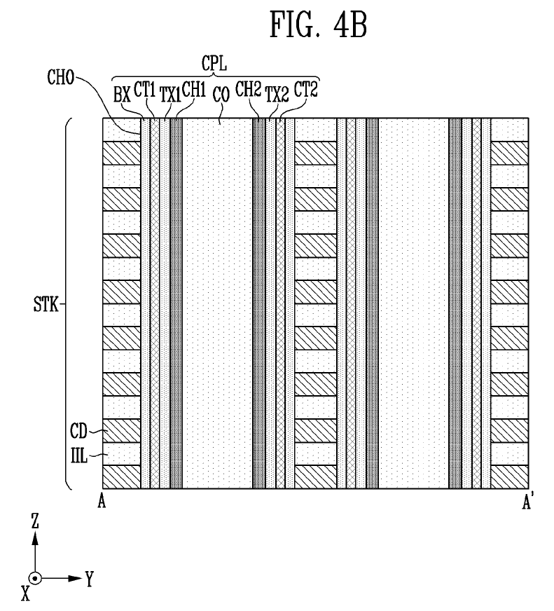

FIGS. 4A and 4B are diagrams illustrating the structure of the memory device 100 according to an embodiment of the present disclosure.

FIG. 4A is a plan view of the memory device 100 according to the present disclosure. For example, FIG. 4A is a plan view of one of the memory blocks BLK1 to BLKi.

Referring to FIG. 4A, channel openings CHO are arranged in the X direction and the Y direction. For example, the channel openings CHO are aligned in the X direction. The channel openings CHO are arranged in an offset or staggered configuration in the Y direction.

The channel openings CHO have an elliptical planar shape. The plane of each channel opening CHO has a minor axis in the X direction and a major axis in the Y direction.

Each of the cell plugs CPL are formed in a corresponding channel openings CHO. The cell plugs CPL may fill the interior of the channel openings CHO. Each of the cell plugs CPL has an elliptical cross-section. The cell plugs CPL are arranged in the X direction and the Y direction.

Each of the cell plugs CPL includes a first data storage pattern CT1, a second data storage pattern CT2, a first channel pattern CH1, and a second channel pattern CH2. Each of the cell plugs CPL includes the first data storage pattern CT separated from the second data storage pattern CT2, and the first channel pattern CH1 separated from the second channel pattern CH2. The first data storage pattern CT1 is spaced apart from the second data storage pattern CT2 in the Y direction. The first channel pattern CH1 is spaced apart from the second channel pattern CH2 in the Y direction.

The first data storage pattern CT1 and the first channel pattern CH1 form a first cell string ST, and the second data storage pattern CT2 and the second channel CH2 form a second cell string ST. One cell plug CPL corresponds to two cell strings ST as shown in the example of FIG. 4A.

FIG. 4B is a cross-sectional view corresponding to line A-A' of FIG. 4A. FIG. 4B is not drawn to scale with respect to FIG. 4A. Referring to FIG. 4B, a stack STK include conductive layers CD and interlayer insulating layers IIL. The conductive layers CD are alternately stacked with the interlayer insulating layers IIL in the Z direction. The conductive layer CD may include at least one of tungsten (W), cobalt (Co), nickel (Ni), molybdenum (Mo), silicon (Si), or polysilicon (poly-Si). The conductive layers CD correspond to gate lines such as the drain select lines DSL, the word lines WL, and the source select lines SSL in FIG. 3. The interlayer insulating layers IIL may include an oxide layer such as a silicon oxide layer.

The channel openings CHO extend through the stack STK. The channel openings CHO extend through the conductive layers CD and the interlayer insulating layers IIL. The channel openings CHO extend in the Z direction. The cell plugs CPL are formed in the channel openings CHO.

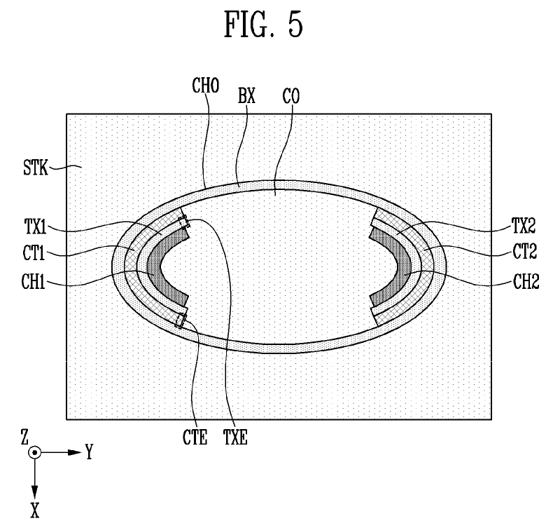

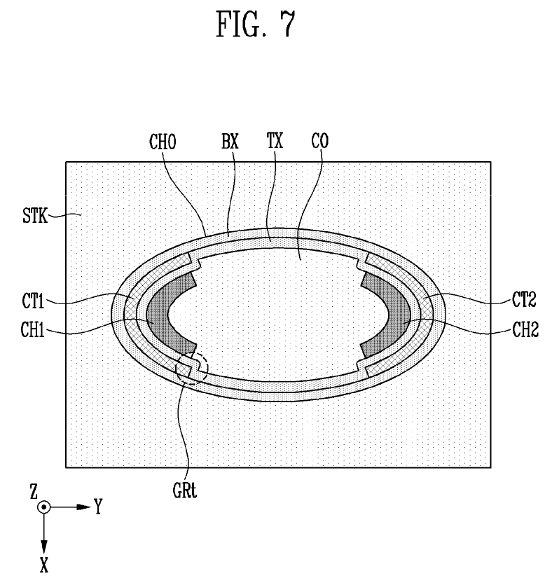

Each of the cell plugs CPL includes a blocking layer BX, the storage patterns CT1 and CT2, a first tunneling pattern TX1 and a second tunneling pattern TX2, the channel patterns CH1 and CH2, and a core pillar CO. The blocking layer BX contacts or is adjacent to a side surface of the stack STK. The data storage patterns CT1 and CT2 are spaced apart in the Y direction. The first tunneling pattern TX1 is spaced apart from the second tunneling pattern TX2 in the Y direction. The first channel pattern CH1 is spaced apart from the second channel CH2 in the Y direction. The core pillar CO is disposed between the channel patterns CH1 and CH2 and may be adjacent to opposing internal walls of the blocking layer BX, as shown in FIG. 5, or opposing internal walls of a tunneling layer TX, as shown in FIG. 7. Although not shown, the cell plugs CPL include capping patterns coupled to the channel patterns CH1 and CH2 on the core pillar CO.

The blocking layer BX and the tunneling patterns TX1 and TX2 may include at least one of an oxide layer, such as a silicon oxide layer, and an oxynitride layer, such as a silicon oxynitride layer. The data storage patterns CT1 and CT2 may include a nitride layer or a variable resistance material. The channel patterns CH1 and CH2 and the capping patterns may include at least one of an undoped silicon layer and a doped silicon layer. The core pillar CO may include an insulating layer such as an oxide layer.

In FIG. 4B, each of the cell plugs CPL includes the first tunneling pattern TX1 separate from the second tunneling pattern TX2, which is one example of the present disclosure. For example, each of the cell plugs CPL may include a single integral tunneling layer. An embodiment in which the cell plug CPL includes the separated tunneling patterns TX1 and TX2 is shown in FIG. 5, and an embodiment in which the cell plug CPL includes a single tunneling layer is shown in FIG. 7.

Referring to FIGS. 4A and 4B, each of the cell plugs CPL has a shape that is symmetrical in the X direction and in the Y direction, for example, with respect to one or more symmetry planes. For example, the first data storage pattern CT1 is symmetrical with the second data storage pattern CT2 in the Y direction, with respect to a first symmetry plane. The first tunneling pattern TX1 is formed symmetrically with respect to the second tunneling pattern TX2 in the Y direction, with respect to the first symmetry plane. The first channel pattern CH1 is formed symmetrically with respect to the second channel pattern CH2 in the Y direction, with respect to the first symmetry plane. The first data storage pattern CT1, the first tunneling pattern TX1, and the first channel pattern CH1 are similar to the second data storage pattern CT2, the second tunneling pattern TX2, and the second channel pattern CH2.

FIG. 5 is a plan view illustrating the structure of the memory device 100 according to an embodiment of the present disclosure.

FIG. 5 is a plan view of the cell plug CPL according to an embodiment of the present disclosure. The cell plug CPL is located in the channel opening CHO having an elliptical cross-section. The channel opening CHO has a major axis in the Y direction in the example of FIG. 5.

The cell plug CPL includes the blocking layer BX, the data storage patterns CT1 and CT2, the tunneling patterns TX1 and TX2, the channel patterns CH1 and CH2, and the core pillar CO. The blocking layer BX, the data storage patterns CT1 and CT2, the tunneling patterns TX1 and TX2, the channel patterns CH1 and CH2, and the core pillar CO extend in the Z direction.

The blocking layer BX contacts the side surface of the stack STK. The blocking layer BX has an elliptical columnar shape such as an elongated ellipse shape. The blocking layer BX extends between the stack STK and the data storage patterns CT1 and CT2. The tunneling patterns TX1 and TX2 extend between the data storage patterns CT1 and CT2 and the channel patterns CH1 and CH2 within an inner wall of the blocking layer BX.

The data storage patterns CT1 and CT2 are aligned on the major axis of the ellipse. For example, the first data storage pattern CT1 is spaced apart from the second data storage pattern CT2 in the Y direction. The tunneling patterns TX1 and TX2 are aligned on the major axis of the ellipse. For example, the first tunneling pattern TX1 is spaced apart from the second tunneling pattern TX2 in the Y direction. The channel patterns CH1 and CH2 are aligned on the major axis of the ellipse. For example, the first channel patterns CH1 is spaced apart from the second channel pattern CH2 in the Y direction.

The data storage patterns CT1 and CT2, the tunneling patterns TX1 and TX2, and the channel patterns CH1 and CH2 have a curved cross-sectional shape.

The first tunneling pattern TX1 is located between the first data storage pattern CT1 and the first channel pattern CH1. The second tunneling pattern TX2 is located between the second data storage pattern CT2 and the second channel pattern CH2. The core pillar CO isolates the first data storage pattern CT1 from the second data storage pattern CT2. The core pillar CO isolates the first channel pattern CH1 from the second channel pattern CH2.

Each of the data storage patterns CT1 and CT2 includes an end CTE. The ends CTE of the first data storage pattern CT1 face the ends CTE of the second data storage pattern CT2. Inner surfaces of the data storage patterns CT1 and CT2 contact the tunneling patterns TX1 and TX2, outer surfaces of the data storage patterns CT1 and CT2 contact the blocking layer BX, and side surfaces or ends of the data storage patterns CT1 and CT2 contact the core pillar CO. The ends CTE of the data storage patterns CT1 and CT2 include the side surfaces of the data storage patterns CT1 and CT2.

Each of the tunneling patterns TX1 and TX2 includes an ends TXE. The ends TXE of the first tunneling pattern TX1 face the ends TXE of the second tunneling pattern TX2. Inner surfaces of the tunneling patterns TX1 and TX2 contact the channel patterns CH1 and CH2 and the core pillar CO, outer surfaces of the tunneling patterns TX1 and TX2 contact the storage patterns CT1 and CT2, and side surfaces or ends of the tunneling patterns TX1 and TX2 contact the core pillar CO. The ends TXE of the tunneling patterns TX1 and TX2 include the side surfaces of the tunneling patterns TX1 and TX2.

Referring to FIG. 5, the ends CTE of the first data storage pattern CT1 do not extend beyond the end TXE of the first tunneling pattern TX1. The ends CTE of the second data storage pattern CT2 do not extend beyond the ends TXE of the second tunneling pattern TX2. For example, the side surfaces of the first data storage pattern CT1 may be formed continuously or linearly with the side surfaces of the first tunneling pattern TX1. The side surfaces of the first data storage pattern CT1 and the side surfaces of the first tunneling pattern TX1 may be formed as a straight line or aligned without a step formed between consecutive side surfaces. As shown in the example of FIG. 5, ends of the first data storage pattern CT1 extend beyond corresponding ends of the first channel pattern CH1, and ends of the first data storage pattern CT1 do not extend beyond corresponding ends of the first tunneling pattern TX1.

Referring to FIG. 5, the ends CTE of the first data storage pattern CT1 extend beyond the first channel pattern CH1. The ends CTE of the second data storage pattern CT2 extend beyond the second channel pattern CH2. For example, the ends CTE of the first data storage pattern CT1 extend closer to the second data storage pattern CT2 than the first channel pattern CH1 extends toward the second data storage pattern CT2. The ends CTE of the second data storage pattern CT2 extend closer to the first data storage pattern CT1 than the second channel pattern CH2 extends toward the first data storage pattern CT1. The ends TXE of the first tunneling pattern TX1 extend further than the first channel pattern CH1 extends. The ends TXE of the second tunneling pattern TX2 extend further than the second channel pattern CH2 extends.

Side surfaces of the first channel pattern CH1 might not be formed smoothly from the side surfaces of the first data storage pattern CT1 and the side surfaces of the first tunneling pattern TX1. A step or offset may form between the side surfaces of the first channel pattern CH1 and the adjacent side surfaces of the data storage pattern CT1. A step or offset may form between the side surfaces of the first channel pattern CH1 and the adjacent side surfaces of the first tunneling pattern TX1.

Side surfaces of the second channel pattern CH2 might not be formed smoothly from the side surfaces of the second data storage pattern CT2 and the side surfaces of the second tunneling pattern TX2. A step or offset may form between the side surfaces of the second channel pattern CH2 and the adjacent side surfaces of the second data storage pattern CT2. A step or offset may form between the side surfaces of the second channel pattern CH2 and the adjacent side surfaces of the second tunneling pattern TX2.

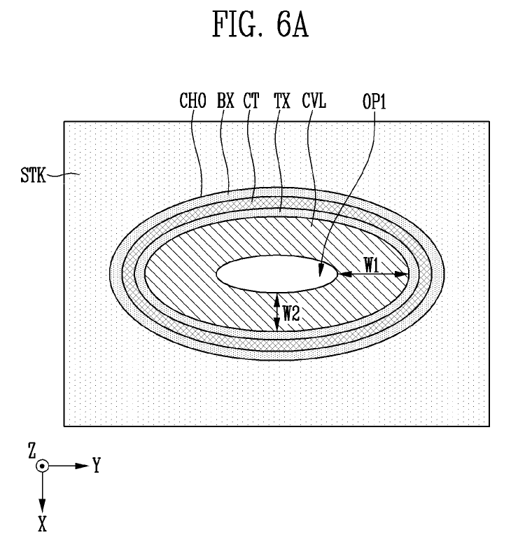

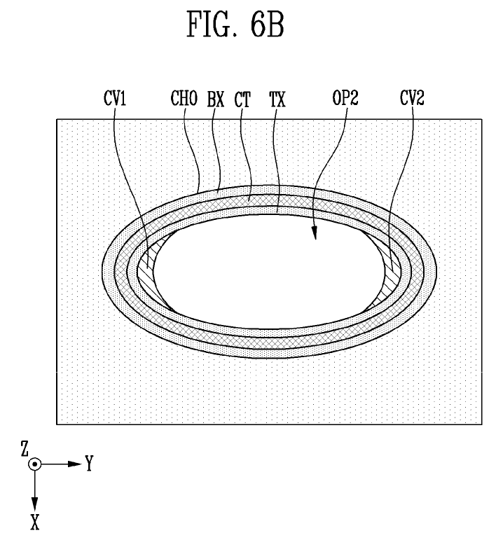

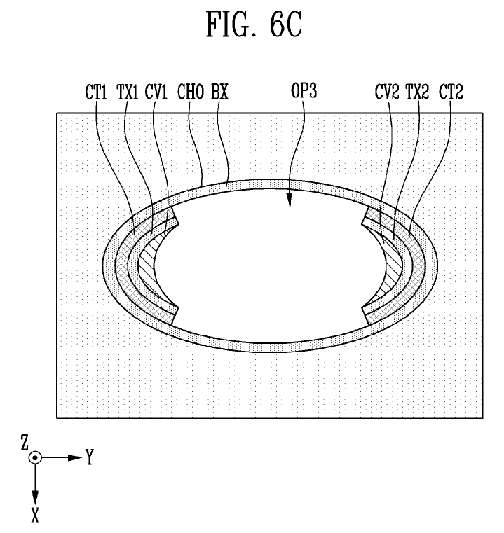

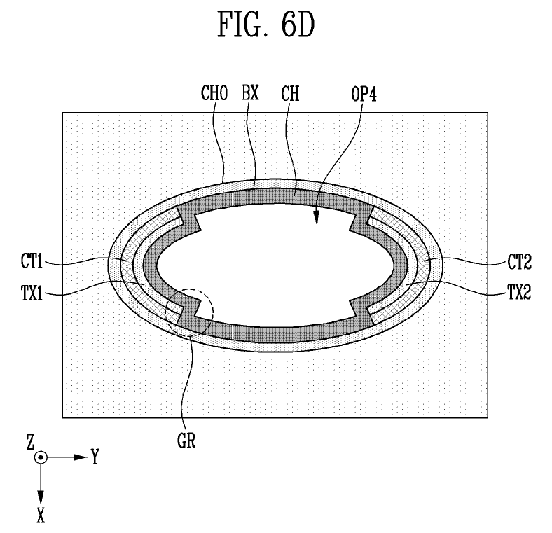

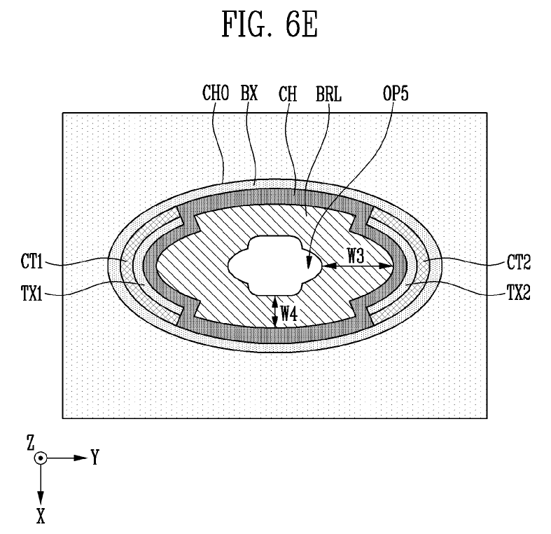

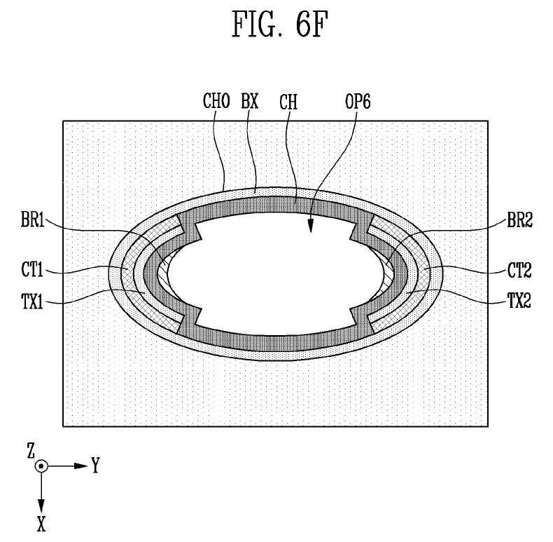

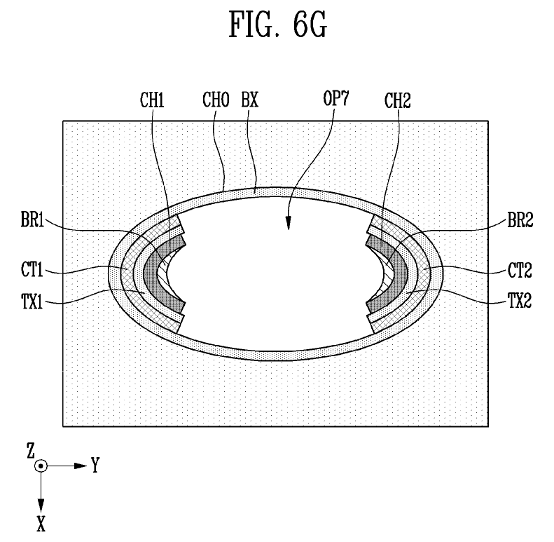

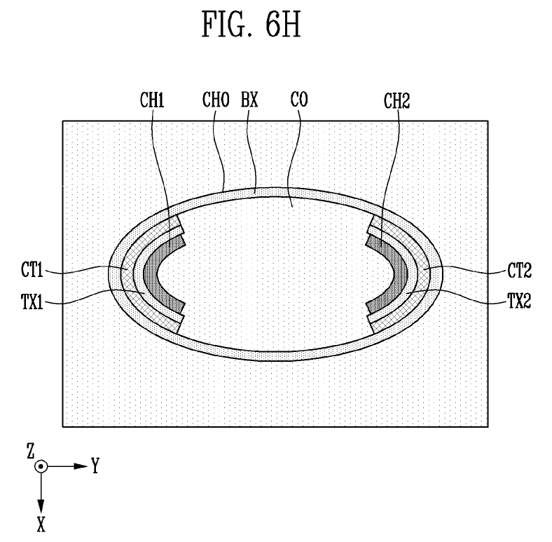

The data storage patterns CT1 and CT2, the f tunneling patterns TX1 and TX2, and the channel patterns CH1 and CH2 included in the cell plug CPL may have uneven or offset features because the process of separating the data storage layer into the data storage patterns CT1 and CT2 and the process of separating the channel layer into the channel patterns CH1 and CH2 are performed separately. Etch processes performed in two separate stages in the present disclosure are described with reference to FIGS. 6A to 6H.

FIGS. 6A to 6H are diagrams illustrating a memory device formed utilizing a method of manufacturing the memory device according to an embodiment of the present disclosure.

Referring to FIG. 6A, the channel opening CHO is formed through the stack STK. The channel opening CHO extends through the stack STK in the Z direction. The channel opening CHO has an elliptical planar shape with a major axis in the Y direction.

The blocking layer BX, a data storage layer CT, and a tunneling layer TX are formed sequentially in the channel opening CHO. The blocking layer BX is formed on the side surface or sidewall of the stack STK. The data storage layer CT is formed on an inner surface of the blocking layer BX. The tunneling layer TX is formed on an inner surface of the data storage layer CT. For example, each of the blocking layer BX, the data storage layer CT, and the tunneling layer TX are sequentially formed through the channel opening CHO. The blocking layer BX and the tunneling layer TX may each include an oxide material. The data storage layer CT may include a nitride material.

A cover layer CVL is formed on an inner surface of the tunneling layer TX. The cover layer CVL may be conformally formed on the inner surface of the tunneling layer TX. The cover layer CVL might not completely fill the tunneling layer TX. A first opening OP1 is formed within the cover layer CVL. The cover layer CVL may include a material having an etch selectivity relative to the data storage layer CT and the tunneling layer TX.

The cover layer CVL may be formed in an elliptical columnar space. The thickness of the cover layer CVL may vary depending on direction. For example, the cover layer CVL has a first thickness W1 along a major-axis of the ellipse, such as the Y direction, and a second thickness W2 along a minor-axis of the ellipse, such as an X direction, where the first thickness W1 is wider than the second thickness W2.

Referring to FIG. 6B, a segment of the cover layer CVL is removed to form a first cover pattern CV1 and a second cover pattern CV2. The segment of the cover layer CVL may be etched through the first opening OP1 of FIG. 6A. Because the segment of the cover layer CVL is removed, a second opening OP2 extends beyond or is wider than the first opening OP1. An isotropic wet etch process may be performed such that a segment of the cover layer CVL is etched and other segments (CV1 and CV2) of the cover layer CVL remain.

Because the cover layer CVL is thickest along the major-axis, in the Y direction, of the ellipse and is thinnest along the minor-axis, in the X direction, of the ellipse, the section of the cover layer CVL located along the minor-axis of the ellipse may be removed before the section located along the major-axis of the ellipse. As a result, the cover patterns CV1 and CV2 are aligned along the major-axis of the ellipse. The first cover pattern CV1 is spaced apart from the second cover pattern CV2 in the Y direction.

The cover patterns CV1 and CV2 contact different sections of the tunneling layer TX. Another section of the tunneling layer TX is exposed through the second opening OP2 between the cover patterns CV1 and CV2. Segments of the data storage layer CT are located between the cover patterns CV1 and CV2 and the blocking layer BX. Another segment of the data storage layer CT is not located between the cover patterns CV1 and CV2 and the blocking layer BX.

Referring to FIG. 6C, segments of the tunneling layer TX are removed to form the tunneling patterns TX1 and TX2. By using the cover patterns CV1 and CV2 as an etch barrier, the segments of the tunneling layer TX may be etched. Thus, sections (TX1 and TX2) of the tunneling layer TX covered by the cover patterns CV1 and CV2 remain as the segments of the tunneling pattern TX are removed. The first tunneling pattern TX1 is spaced apart from the second tunneling pattern TX2 in the Y direction. The tunneling patterns TX1 and TX2 have a curved shape. The tunneling patterns TX1 and TX2 extend in the Z direction.

Segments of the data storage layer CT are removed to form the data storage patterns CT1 and CT2. Segments of the data storage layer CT may be etched using the cover patterns CV1 and CV2 as an etch barrier. Thus, sections of the data storage layer CT between the cover patterns CV1 and CV2 and the blocking layer BX remain as sections of the storage pattern CT are removed. The first data storage pattern CT1 is spaced apart from the second data storage pattern CT2 in the Y direction. The data storage patterns CT1 and CT2 have a curved shape. The data storage patterns CT1 and CT2 extend in the Z direction.

Because the tunneling layer TX and the data storage layer CT are etched using the same etch barriers, the cover patterns CV1 and CV2, the side surfaces of the data storage patterns CT1 and CT2 extend evenly or smoothly with the side surfaces of the tunneling patterns TX1 and TX2. Thus, no step may form between the side surfaces of the data storage patterns CT1 and CT2 and the adjacent side surfaces of the tunneling patterns TX1 and TX2. For example, the side surface of tunneling pattern TX1 and the adjacent side surface of data storage pattern CT1 may form a line.

As the segment of the tunneling layer TX and the segment of the data storage layer CT are removed through the second opening OP2, a third opening OP3 extends or expands in the X direction relative to the second opening OP2. The third opening OP3 has a cross-sectional shape including an ellipse and extensions extending in the X direction from the ellipse in the example of FIG. 6C.

The processes described with respect to FIGS. 6A to 6C may be referred to as a primary etch process that separates the data storage layer CT into the first data storage pattern CT1 and the second data storage pattern CT2.

Referring to FIG. 6D, the cover patterns CV1 and CV2 are removed. A channel layer CH is formed in the third opening OP3. The channel layer CH is formed on the blocking layer BX, the data storage patterns CT1 and CT2, and the tunneling patterns TX1 and TX2. The channel layer CH may include polysilicon.

The channel layer CH covers sides of the data storage patterns CT1 and CT2. A section of the channel layer CH directly contacts the inner surface of the blocking layer BX in this example. A section of the channel layer CH directly contacts the inner surfaces and the side surfaces of the tunneling patterns TX1 and TX2 in this example. A sections of the channel layer CH directly contact the side surfaces of the data storage patterns CT1 and CT2. Because the channel layer CH is formed within the third opening OP3, a fourth opening OP4 is smaller than the third opening OP3.

The channel layer CH is conformally formed on the blocking layer BX, the data storage patterns CT1 and CT2, and the tunneling patterns TX1 and TX2. The channel layer CH includes angled regions GR. For example, the channel layer CH includes the angled regions GR at the ends CTE of the data storage patterns CT1 and CT2 and at the ends TXE of the tunneling patterns TX1 and TX2. The angled regions GR of the channel layer CH include a protruding region from the elliptical shape within the fourth opening OP4.

Referring to FIG. 6E, a barrier layer BRL is formed in the fourth opening OP4. The barrier layer BRL is formed on an inner surface of the channel layer CH. The barrier layer BRL is conformally formed on the inner surface of the channel layer CH. The barrier layer BRL does not completely fill the fourth opening OP4. A fifth opening OP5 is formed in the barrier layer BRL. The barrier layer BRL includes a material having an etch selectivity relative to the channel layer CH. For example, the barrier layer BRL may include a material similar to the material of the cover layer CVL.

The thickness of the barrier BRL varies depending on direction. For example, the barrier layer BRL has a third thickness W3 in the Y direction and a fourth thickness W4 in the X direction, where the third thickness W3 is wider than the fourth thickness W4. When the fourth opening OP4 has the shape of an ellipse and extensions projecting from the ellipse in the X direction, the thickness of the barrier layer BRL deposited along the major-axis of the ellipse is greater than other thicknesses of the barrier layer BRL.

According to the primary etch process described with respect to FIGS. 6A to 6C, the third opening OP3 and the fourth opening OP4 include extensions extending in the X direction from an elliptical shape. When a channel layer and a barrier layer are formed in an opening having an elliptical cross-section, sufficient space along the minor axis of the ellipse might not be present to deposit material layers. When the opening is expanded along the minor-axis of the ellipse, such as in the present example, sufficient space results to deposit the channel layer CH and the barrier layer BRL. Therefore, difficulty of depositing the channel layer CH and the barrier layer BRL in an elliptical channel opening may be reduced.

Referring to FIG. 6F, a segment of the barrier layer BRL is removed to form a first barrier pattern BR1 and a second barrier pattern BR2. The segment of the barrier layer BRL may be etched through the fifth opening OP5 of FIG. 6E. Because the segment of the barrier layer BRL is removed, a sixth opening OP6 extends beyond or expands the fifth opening OP5. An isotropic wet etch process may be performed such that a segment of the barrier layer BRL is etched and a section of the barrier layer BRL remains.

Because the barrier layer BRL is thicker in the Y direction than in the X direction, the segment of the barrier layer BRL located in the X direction may be removed before the segment located in the Y direction. Thus, the barrier patterns BR1 and BR2 are aligned in the Y direction. The first barrier pattern BR1 is spaced apart from the second barrier pattern BR2 in the Y direction.

The patterns BR1 and BR2 contact sections of the channel layer CH. A section of the channel layer CH is exposed through the sixth opening OP6 between the barrier patterns BR1 and BR2. The angled regions GR of the channel layer CH are not covered by the barrier patterns BR1 and BR2. The barrier patterns BR1 and BR2 are located on the channel layer CH near the tunneling patterns TX1 and TX2 and the data storage patterns CT1 and CT2.

Referring to FIG. 6G, segments of the channel layer CH are removed to form the first channel pattern CH1 and the second channel pattern CH2. By using the barrier patterns BR1 and BR2 as an etch barrier, the segments of the channel layer CH are etched. Thus, sections of the channel layer CH covered by the barrier patterns BR1 and BR2 remain as segments of the channel pattern CH are removed. The first channel pattern CH1 is spaced apart from the second channel pattern CH2 in the Y direction. The channel patterns CH1 and CH2 extend in the Z direction. Because segments of the channel layer CH are removed through the sixth opening OP6, a seventh opening OP7 is formed that extends or expands in the X direction relative to the sixth opening OP6.

When segments of the channel layer CH are removed using the barrier patterns BR1 and BR2 as the etch barrier, the angled regions GR of the channel layer CH are removed. Thus, the channel patterns CH1 and CH2 have a curved shape corresponding to vertices of an ellipse.

Because the channel layer CH is etched using the tunneling layer TX or the data storage layer CT as an etch barrier, and the tunneling layer TX and the data storage layer CT are etched using different etch barriers, the barrier patterns BR1 and BR2, the side surfaces of the channel patterns CH1 and CH2 do not extend smoothly from or align with the side surfaces of the data storage patterns CT1 and CT2 and the side surfaces of the tunneling patterns TX1 and TX2. A step between the side surfaces of the channel patterns CH1 and CH2 and the side surfaces of the tunneling patterns TX1 and TX2 is present, such that consecutive side surfaces are not formed in a line. For example, the side surface of the first channel pattern CH1 is offset from or does not align with the side surface of the first tunneling pattern TX1.

The processes described with reference to FIGS. 6D to 6G may be referred to as a secondary etch process that separates the channel layer CH into the first channel pattern CH1 and the second channel pattern CH2.

Referring to FIG. 6H, the barrier patterns BR1 and BR2 are removed. A core material layer, such as an oxide layer, fills the 7th opening OP7 to form the core pillar CO. The core pillar CO isolates the first data storage pattern CT1, the first tunneling pattern TX1, and the first channel pattern CH1 from the second data storage pattern CT2, the second tunneling pattern TX2, and the second channel pattern CH2.

FIG. 7 is a plan view illustrating the structure of a memory device according to an embodiment of the present disclosure.

FIG. 7 is a top view of the cell plug CPL according to an embodiment of the present disclosure. The cell plug CPL is located in the channel opening CHO that has an elliptical cross-section. The channel opening CHO has a major axis in the Y direction.

The cell plug CPL includes the blocking layer BX, the data storage patterns CT1 and CT2, the tunneling layer TX, the channel patterns CH1 and CH2, and the core pillar CO. The blocking layer BX, the data storage patterns CT1 and CT2, the tunneling layer TX, the channel patterns CH1 and CH2, and the core pillar CO extend in the Z direction.

The blocking layer BX contacts the side surface of the stack STK. The blocking layer BX has an elliptical columnar shape. The blocking layer BX extends between the stack STK and the data storage patterns CT1 and CT2 and between the stack STK and the tunneling layer TX.

The data storage patterns CT1 and CT2 are formed along the inner wall of the blocking layer BX. The data storage patterns CT1 and CT2 have a curved cross-section. The data storage patterns CT1 and CT2 are aligned with the major axis of an ellipse. For example, the first storage pattern CT1 is spaced apart from the second data storage pattern CT2 in the Y direction. The first data storage pattern CT1 is insulated from the second data storage pattern CT2 by the tunneling layer TX and the core pillar CO.

The data storage patterns CT1 and CT2 include ends. The ends of the first data storage pattern CT1 face the ends of the second data storage pattern CT2. Inner surfaces and side surfaces of the data storage patterns CT1 and CT2 face the tunneling layer TX and outer surfaces of the data storage patterns CT1 and CT2 face the blocking layer BX. The ends of the data storage patterns CT1 and CT2 include the side surfaces of the data storage patterns CT1 and CT2.

The tunneling layer TX extends along an inner surface of the blocking layer BX and the inner surfaces of the data storage patterns CT1 and CT2. The tunneling layer TX contacts part of the inner surface of the blocking layer BX. The tunneling layer TX extends between the first data storage pattern CT1 and the first channel pattern CH1 and extends between the second data storage pattern CT2 and the second channel pattern CH2. The tunneling layer TX contacts the inner surfaces and the side surfaces of the data storage patterns CT1 and CT2.

The channel patterns CH1 and CH2 are formed along an inner wall of the tunneling layer TX. The channel patterns CH1 and CH2 have a curved cross-section. The channel patterns CH1 and CH2 are aligned along the major axis of the ellipse. For example, the first channel pattern CH1 is spaced apart from the second channel pattern CH2 in the Y direction.

Outer surfaces of the channel patterns CH1 and CH2 contact the tunneling layer TX, and inner surfaces and side surfaces of the channel patterns CH1 and CH2 contact the core pillar CO. The core pillar CO insulates the first channel pattern CH1 from the second channel pattern CH2.

Referring to FIG. 7, the tunneling layer TX includes angled regions GRt at the ends of the data storage patterns CT1 and CT2. The tunneling layer TX is conformally formed on the inner surface of the blocking layer BX and the inner surfaces of the data storage patterns CT1 and CT2. Because the tunneling layer TX is formed on the data storage patterns CT1 and CT2 that are separated from each other, the tunneling layer TX include the angled regions GRt at the ends of the data storage patterns CT1 and CT2.

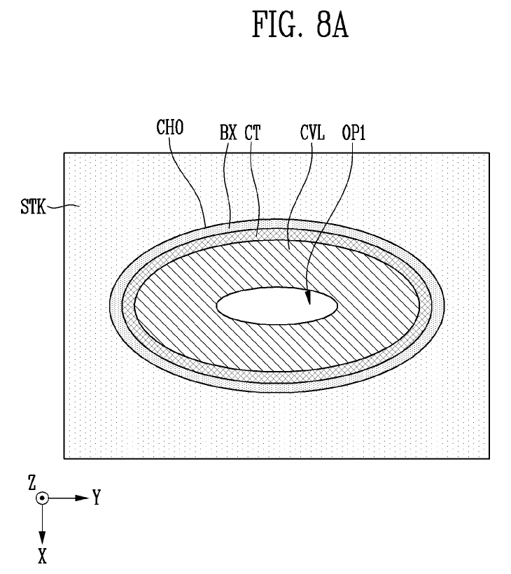

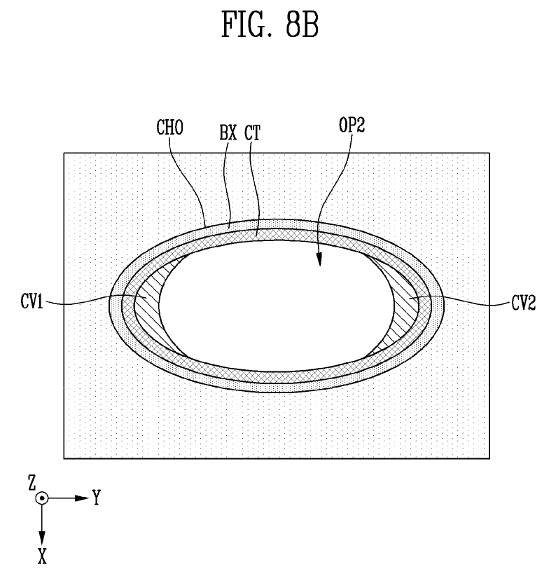

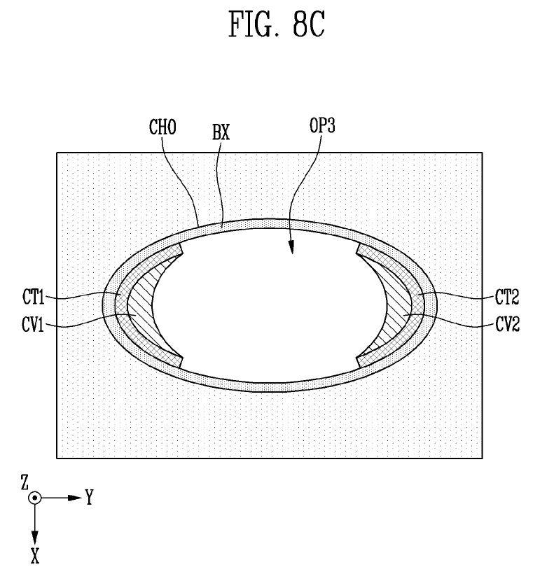

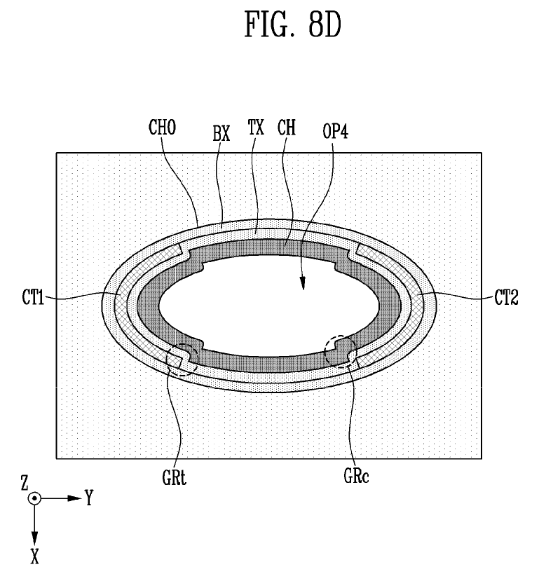

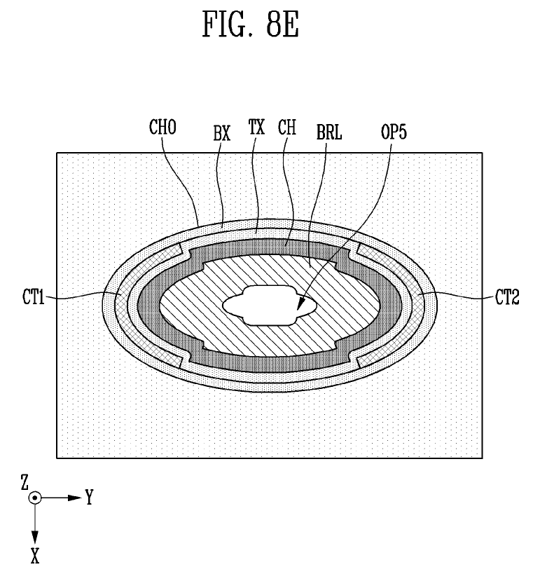

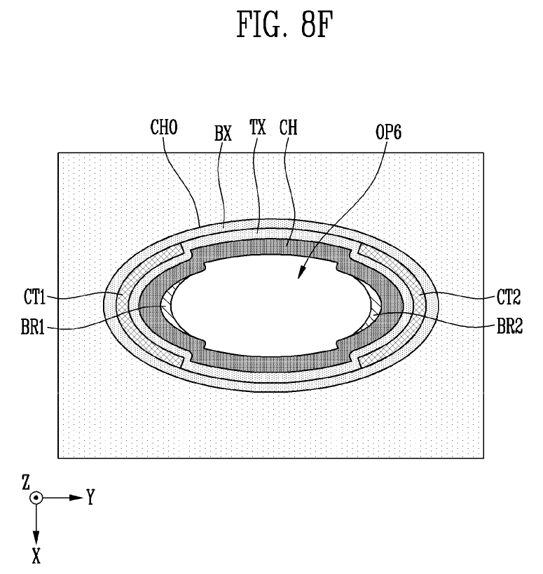

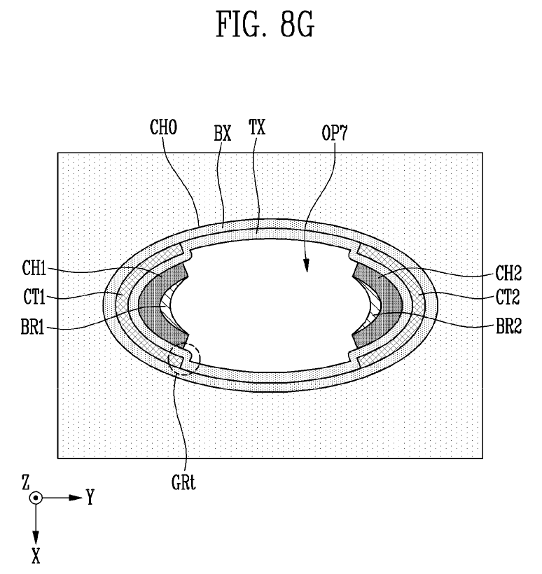

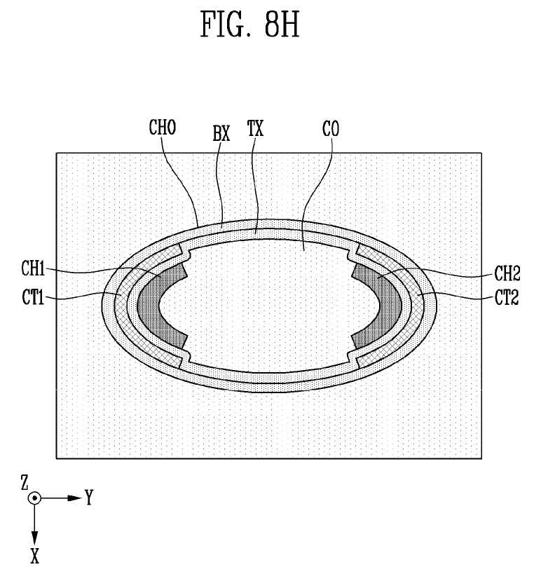

Because the process of separating the data storage layer into the data storage patterns CT1 and CT2 is performed separately from the process of separating the channel layer into the channel patterns CH1 and CH2, the tunneling layer TX included in the cell plug CPL has the features described with respect to FIG. 7. Etch processes performed in two separate stages are described with reference to FIGS. 8A to 8H.

FIGS. 8A to 8H are diagrams illustrating a memory device formed utilizing a method of manufacturing the memory device according to an embodiment of the present disclosure.

Referring to FIG. 8A, the channel opening CHO is formed through the stack STK. The channel opening CHO extends through the stack STK in the Z direction. The channel opening CHO has an elliptical planar shape with a major axis in the Y direction.

The blocking layer BX and the data storage layer CT are formed sequentially in the channel opening CHO. The blocking layer BX is formed on the side surface or sidewall of the stack STK. The data storage layer CT is formed on an inner surface of the blocking layer BX. For example, the blocking layer BX is formed along a sidewall of the stack STK exposed through the channel opening CHO, and the data storage layer CT is formed on the inner surface of the blocking layer BX. The blocking layer BX may include an oxide material. The data storage layer CT may include a nitride material.

The cover layer CVL is formed on an inner surface of the data storage layer CT. The cover layer CVL is formed conformally on the inner surface of the data storage layer CT. The cover layer CVL might not completely fill the data storage layer CT. A first opening OP1 is formed in the cover layer CVL. The cover layer CVL may include a material having an etch selectivity relative to the data storage layer CT.

The cover layer CVL is formed in an elliptical columnar space. The thickness of the cover layer CVL may vary depending on direction. For example, the cover layer CVL has a first thickness along the major-axis, in the Y direction, of the ellipse and a second thickness along the minor-axis, in the X direction, of the ellipse, where the first thickness is wider than the second thickness.

Referring to FIG. 8B, a segment of the cover layer CVL is removed to form the first cover pattern CV1 and the second cover pattern CV2. Through the first opening OP1 of FIG. 8A, the segment of the cover layer CVL is etched. Because the segment of the cover layer CVL is removed, the second opening OP2 extends beyond or is wider than the first opening OP1. An isotropic wet etch process may be performed such that a segment of the cover layer CVL is etched and other segments (CV1 and CV2) of the cover layer CVL remain.

Because the cover layer CVL is thickest along the major-axis, in the Y direction, of the ellipse and is thinnest along the minor-axis, in the X direction, of the ellipse, the section of the cover layer CVL located along the minor-axis of the ellipse may be removed before the section located along the major-axis of the ellipse. As a result, the cover patterns CV1 and CV2 are aligned along the major-axis of the ellipse. The first cover pattern CV1 is spaced apart from the second cover pattern CV2 in the Y direction.

The cover patterns CV1 and CV2 contact different sections of the data storage layer CT. Another section of the data storage layer CT is exposed through the second opening OP2 between the cover patterns CV1 and CV2.

Referring to FIG. 8C, segments of the data storage layer CT are removed to form the data storage patterns CT1 and CT2. The segments of the data storage layer CT are etched using the cover patterns CV1 and CV2 as an etch barrier. Thus, sections (CT1 and CT2) of the data storage layer CT covered by the cover patterns CV1 and CV2 remain as the segments of the data storage patterns CT1 and CT2are removed. The first data storage pattern CT1 is spaced apart from the second data storage pattern CT2 in the Y direction. The data storage patterns CT1 and CT2 have a curved shape. The data storage patterns CT1 and CT2 extend in the Z direction.

Because segments of the data storage layer CT are removed through the second opening OP2, the third opening OP3 extends in the X direction beyond the second opening OP2. The third opening OP3 has a cross-sectional shape including an ellipse and extensions extending in the X direction from the ellipse in the example of FIG. 8C.

The processes described with respect to FIGS. 8A to 8C may be referred to as a primary etch process that separates the data storage layer CT into the first data storage pattern CT1 and the second data storage pattern CT2.

Referring to FIG. 8D, the cover patterns CV1 and CV2 are removed. The tunneling layer TX is formed in the third opening OP3. The tunneling layer TX is formed on the blocking layer BX and the data storage patterns CT1 and CT2. The tunneling layer TX covers the data storage patterns CT1 and CT2 that are separated. A section of the tunneling layer TX directly contacts an inner surface of the blocking layer BX in this example. A section of the tunneling layer TX directly contacts inner surfaces and side surfaces of the data storage patterns CT1 and CT2.

The tunneling layer TX is conformally formed on the blocking layer BX and the data storage patterns CT1 and CT2. The tunneling layer TX includes the angled regions GRt. For example, the tunneling layer TX include the angled regions GRt at the ends of the data storage patterns CT1 and CT2. The angled regions GRt of the tunneling layer TX include an angled or protruding region from the elliptical shape within the fourth opening OP4.

The channel layer CH is formed in the third opening OP3. The channel layer CH is formed on the tunneling layer TX. The channel layer CH extends along the inner surface of the tunneling layer TX. The tunneling layer TX is disposed between the channel layer CH and the first data storage pattern CT1 that is separated from the second data storage pattern CT2. Because the tunneling layer TX and the channel layer CH are formed within the third opening OP3, the fourth opening OP4 is smaller than the third opening OP3.

The channel layer CH is conformally formed on the tunneling layer TX. The channel layer CH includes angled regions GRc. For example, the channel layer CH includes the angled regions GRc at the angled regions GRt of the tunneling layer TX. The channel layer CH includes the angled regions GRc at the ends of the data storage patterns CT1 and CT2. The angled regions GRc of the channel layer CH include a protruding region from the elliptical shape within the fourth opening OP4.

Referring to FIG. 8E, the barrier layer BRL may be formed in the fourth opening OP4. The barrier layer BRL is formed on an inner surface of the channel layer CH. The barrier layer BRL is formed conformally on the inner surface of the channel layer CH. The barrier layer BRL does not completely fill the fourth opening OP4. A fifth opening OP5 is formed in the barrier layer BRL. The barrier layer BRL includes a material having an etch selectivity relative to the channel layer CH and the tunneling layer TX. For example, the barrier layer BRL may include a material similar to the material of the cover layer CVL.

The thickness of the barrier BRL varies depending on direction. For example, the barrier layer BRL has a third thickness in the Y direction and a fourth thickness in the X direction, where the third thickness W3 is wider than the fourth thickness W4. When the fourth opening OP4 has the shape of an ellipse and extensions projecting from the ellipse in the X direction, the thickness of the barrier layer BRL along the major-axis of the ellipse is a greater thickness than other thicknesses of the barrier layer BRL.

According to the primary etch process described with respect to FIGS. 8A to 8C, the third opening OP3 and the fourth opening OP4 extensions extending in the X direction from an elliptical shape. When a tunneling layer, a channel layer, and a barrier layer are formed in an opening having an elliptical cross-section, sufficient space along the minor axis of the ellipse might not be present to deposit material layers. When the opening is expanded along the minor-axis of the ellipse, such as in the present example, sufficient space results to deposit the tunneling layer TX, the channel layer CH, and the barrier layer BRL. Therefore, difficulty of depositing the tunneling layer TX, the channel CH, and the barrier layer BRL in an elliptical channel opening may be reduced.

Referring to FIG. 8F, a segment of the barrier layer BRL is removed to form the barrier patterns BR1 and BR2. The segment of the barrier layer BRL may be etched through the fifth opening OP5 of FIG. 8E. Because the segment of the barrier layer BRL is removed, the sixth opening OP6 extends beyond or expands the fifth opening OP5. An isotropic wet etch process may be performed such that a segment of the barrier layer BRL is etched and a section of the barrier layer remains.

Because the barrier layer BRL is thicker in the Y direction than in the X direction, the segment of the barrier layer BRL located in the X direction may be removed before removing the segment located in the Y direction. Thus, the barrier patterns BR1 and BR2 are aligned in the Y direction. The first barrier pattern BR1 is spaced apart from the second barrier pattern BR2 in the Y direction.

The barrier patterns BR1 and BR2 contact sections of the channel layer CH. A section of the channel layer CH is exposed through the sixth opening OP6 between the barrier patterns BR1 and BR2. The angled regions GRc of the channel layer CH are not covered by the barrier patterns BR1 and BR2. The barrier patterns BR1 and BR2 are located on the channel layer CH near the data storage patterns CT1 and CT2.

Referring to FIG. 8G, segments of the channel layer CH are removed to form the channel patterns CH1 and CH2. By using the barrier patterns BR1 and BR2 as an etch barrier, the segments of the channel layer CH are etched. Thus, sections of the channel layer CH covered by the barrier patterns BR1 and BR2 remain as segments of the channel pattern CH are removed. The first channel pattern CH1 is spaced apart from the second channel pattern CH2 in the Y direction. The channel patterns CH1 and CH2 extend in the Z direction. Because segments of the channel layer CH are removed through the sixth opening OP6, the seventh opening OP7 is formed that extends or expands in the X direction relative to the sixth opening OP6.

When segments of the channel layer CH are removed using the barrier patterns BR1 and BR2 as the etch barrier, the angled regions GRc of the channel layer CH are removed. Thus, the channel patterns CH1 and CH2 have a curved shape corresponding to vertices of an ellipse.

As the angled regions GRc of the channel layer CH are removed, the angled regions GRt of the tunneling layer TX are exposed through the seventh opening OP7. The angled regions GRt of the tunneling layer TX are located between an ends of one of the channel patterns CH1 and CH2 and an ends of one of the data storage patterns CT1 and CT2.

The processes described with reference to FIGS. 8D to 8G may be referred to as a secondary etch process that separates the channel layer CH into the first channel pattern CH1 and the second channel pattern CH2.

Referring to FIG. 8H, the barrier patterns BR1 and BR2 are removed. A core material layer fills the 7th opening OP7 to form the core pillar CO. The core pillar CO insulates the first data storage pattern CT1 and the first channel pattern CH1 from the second data storage pattern CT2 and the second channel pattern CH2.

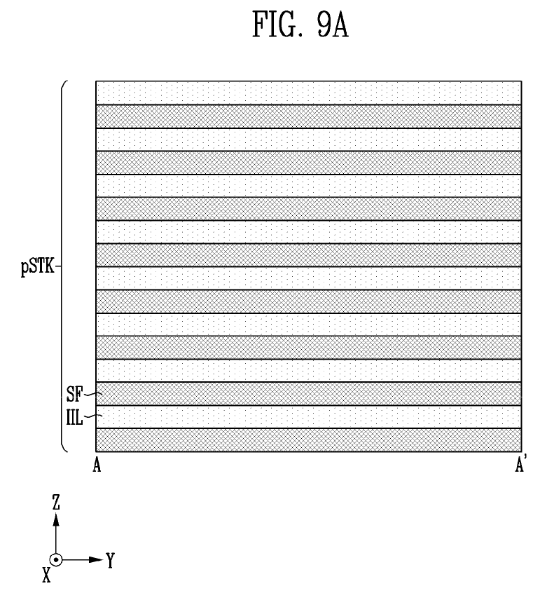

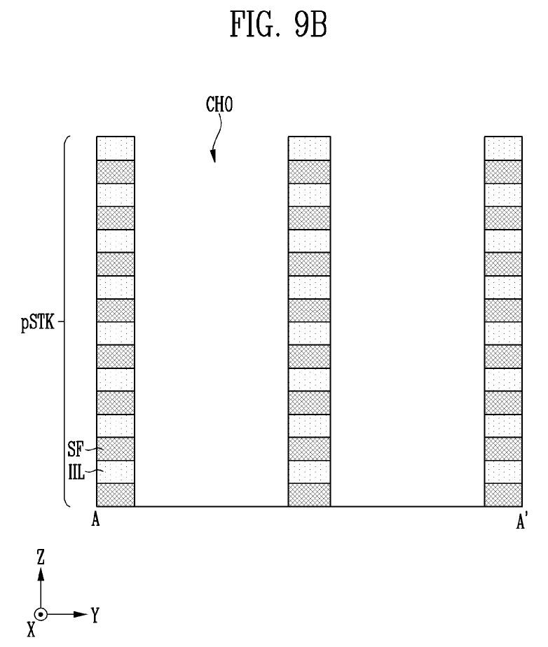

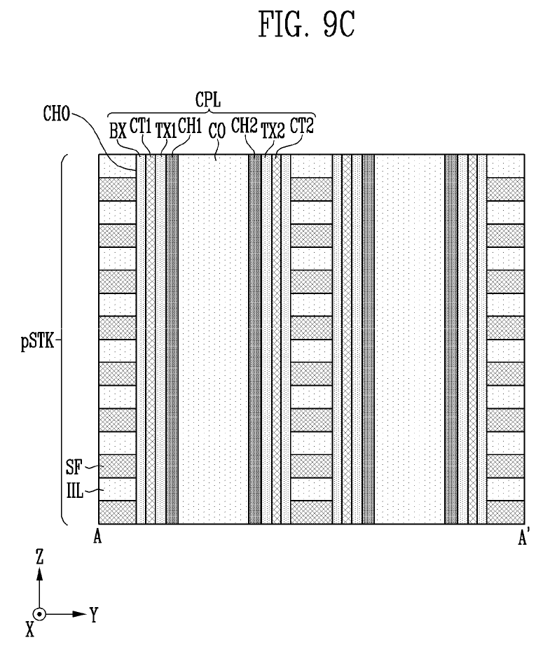

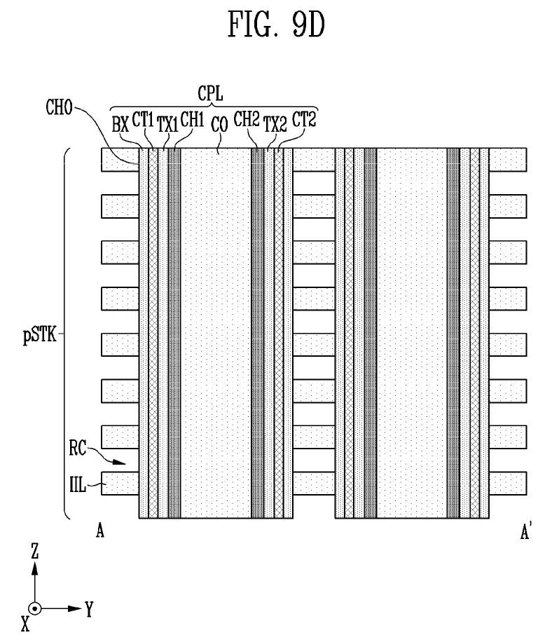

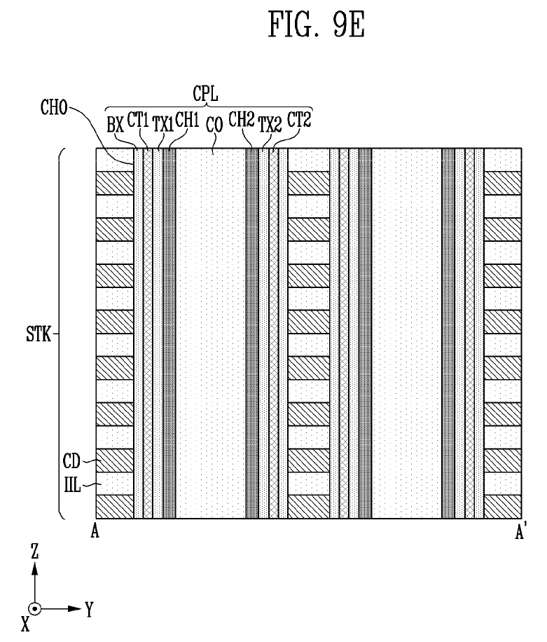

FIGS. 9A to 9E are diagrams illustrating a memory device formed utilizing a method of manufacturing the memory device according to an embodiment of the present disclosure.

FIGS. 9A to 9E are diagrams illustrating a memory device formed utilizing a method of forming the cell plugs CPL according to an embodiment of the present disclosure.

Referring to FIG. 9A, a preliminary stack pSTK is formed including the interlayer insulating layers IIL alternately stacked with the sacrificial layers SF. The interlayer insulating layers IIL and the sacrificial layer SF are stacked in the Z direction. The interlayer insulating layers IIL may include an insulating material. For example, the interlayer insulators IIL may include an oxide layer (e.g., a silicon oxide layer). The sacrificial layers SF may include a material that may be selectively removed in a subsequent process. The sacrificial layers SF may include a material having a different etch selectivity from the interlayer insulating layers IIL. For example, the sacrificial layers SF may include a nitride layer.

Referring to FIG. 9B, the channel openings CHO are formed through the preliminary stack pSTK. The channel openings CHO extend through the preliminary stack pSTK in the Z direction. The channel openings CHO are arranged in the X direction and the Y direction. The side surfaces of the sacrificial layers SF and the interlayer insulating layers IIL are exposed through the channel openings CHO.

Referring to FIG. 9C, a cell plug CPL is formed in each of the channel openings CHO. The cell plug CPL may have a structure according to the embodiment described with reference to FIGS. 5 and 6A to 6H or according to the embodiment described with reference to FIGS. 7 and 8A to 8H. For example, the cell plug CPL includes the blocking layer BX, the data storage patterns CT1 and CT2, the tunneling patterns TX1 and TX2 (or the tunneling layer TX), the channel patterns CH1 and CH2, and the core pillar CO.

Referring to FIG. 9D, the sacrificial layer SF are removed to form recesses RC. Because the sacrificial layer SF is removed, space is formed between the interlayer insulating layers IIL. The cell plugs CPL support the interlayer insulating layers IIL that are spaced apart.

Referring to FIG. 9E, a conductive layer CD is formed between consecutive interlayer insulating layers IIL to form the stack STK. The conductive layers CD fill the recesses RC formed when removing the sacrificial layers SF. The conductive layers CD may include a conductive material.

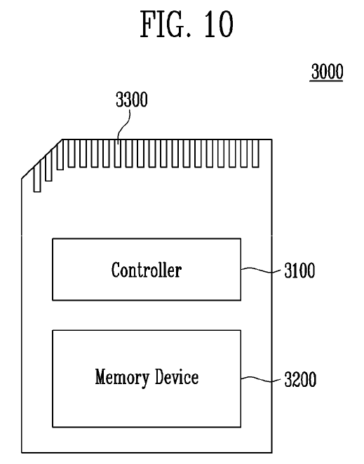

FIG. 10 is a block diagram illustrating a memory card system 3000 according to an embodiment of the present disclosure.

Referring to FIG. 10, the memory card system 3000 includes a controller 3100, a memory device 3200, and a connector 3300.

The controller 3100 is coupled to the memory device 3200. The controller 3100 accesses the memory device 3200. For example, the controller 3100 controls a program operation, a read operation, an erase operation, and a background operation of the memory device 3200. The controller 3100 is configured as an interface between the memory device 3200 and a host. The controller 3100 is configured to drive or execute firmware that controls the memory device 3200. For example, the controller 3100 may include components, such as a Random-Access Memory (RAM), a processing unit, a host interface, a memory interface, and an ECC circuit.

The controller 3100 communicates with an external device through the connector 3300. The controller 3100 may communicate with an external device, such as a host, based on a communication protocol. For example, the controller 3100 may communicate with the external device using at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. In an embodiment, the connector 3300 is configured according to at least one of these various communication protocols.

The memory device 3200 includes a plurality of memory cells and is configured similarly to the memory device 100 shown in FIG. 1, including memory cells configured according to any of FIGS. 4A, 4B, 5, 6A To 6H, 7, 8A to 8H and 9A to 9E.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

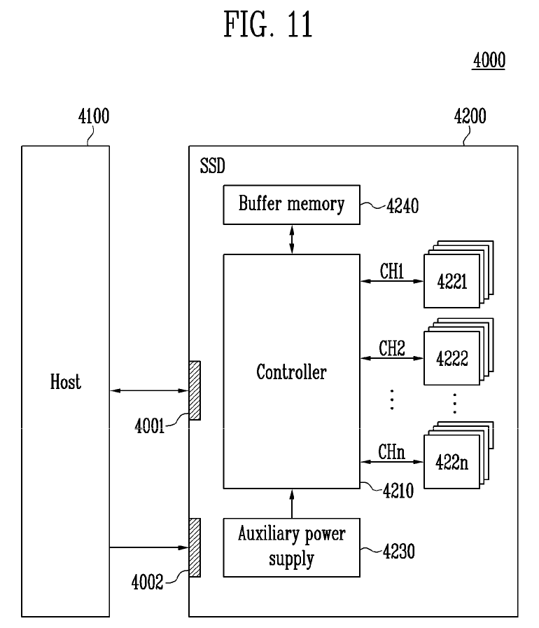

FIG. 11 is a block diagram illustrating a solid-state drive (SSD) system 4000 including a memory device according to an embodiment of the present disclosure.

Referring to FIG. 11, the SSD system 4000 includes a host 4100 and an SSD 4200. The SSD system 4200 exchanges signals with the host 4100 via a signal connector 4001 and receives power through a power connector 4002. The SSD 4200 includes a controller 4210, a plurality of memory devices 4221 to 422n, an auxiliary power supply 4230, and a buffer memory 4240.

The controller 4210 controls the plurality of memory devices 4221 to 422n in response to the signals received from the host 4100. In an embodiment, the signals are based on the interfaces of the host 4100 and the SSD 4200. For example, the signals may be configured according to at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) interfaces.

The plurality of memory devices 4221 to 422n includes a plurality of memory cells configured to store data. Each of the plurality of memory devices 4221 to 422n is configured similarly to the memory device 100 shown in FIG. 1, including memory cells configured according to any of FIGS. 4A, 4B, 5, 6A to 6H, 7, 8A to 8H, and 9A to 9E. The plurality of memory devices 4221 to 422n communicates with the controller 4210 through channels CH1 to CHn.

The auxiliary power supply 4230 is coupled to the host 4100 through the power connector 4002. The auxiliary power supply 4230 is supplied and charged with power from the host 4100. The auxiliary power supply 4230 supplies the power to the SSD 4200 when the power supplied from the host 4100 is not reliable or smooth. The auxiliary power supply 4230 may be located inside or outside the SSD 4200. For example, the auxiliary power supply 4230 is disposed on a main board and supplies auxiliary power to the SSD 4200.

The buffer memory 4240 is a buffer memory of the SSD 4200. For example, the buffer memory 4240 stores data received from the host 4100 or data received from the plurality of memory devices 4221 to 422n or stores metadata, such as mapping tables, of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to the present disclosure, by improving a process of forming a cell plug, the difficulty of manufacturing the memory device may be reduced and integration density of a memory device may be improved or increased.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A method of manufacturing a memory device, the method comprising:
forming a channel opening extending through a stack in a first direction;
forming, in the channel opening, a first data storage pattern spaced apart from a second data storage pattern in a second direction perpendicular to the first direction;
forming a channel layer inside the first data storage pattern and the second data storage pattern;
forming, inside the channel layer, a first barrier pattern spaced apart from a second barrier pattern in the second direction; and
forming a first channel pattern spaced apart from a second channel pattern spaced apart in the second direction by removing a segment of the channel layer between the first barrier pattern and the second barrier pattern.

2. The method of claim 1, wherein the channel opening has an elliptical planar shape with a major axis in the second direction.

3. The method of claim 1, wherein forming the first data storage pattern and the second data storage pattern comprises:
forming a data storage layer inside a sidewall of the stack exposed through the channel opening;
forming, within the data storage layer, a first cover pattern spaced apart from a second cover pattern in the second direction;
forming the first data storage pattern and the second data storage pattern by removing a segment of the data storage layer between the first cover pattern and the second cover pattern; and
removing the first cover pattern and the second cover pattern.

4. The method of claim 3, further comprising forming a blocking layer on the sidewall of the stack before forming the data storage layer.

5. The method of claim 4, further comprising forming a section of the channel layer directly contacting the blocking layer.

6. The method of claim 3, further comprising forming a tunneling layer on an inner surface of the data storage layer.

7. The method of claim 6, further comprising forming a first tunneling pattern spaced apart from a second tunneling pattern in the second direction by removing a segment of the tunneling layer between the first cover pattern and the second cover pattern.

8. The method of claim 7, further comprising forming a first section of the channel layer directly contacting the first tunneling pattern and forming a second section of the channel layer directly contacting the second tunneling pattern.

9. The method of claim 3, wherein the first barrier pattern, the second barrier pattern, the first cover pattern and the second cover pattern comprise similar material.

10. The method of claim 3, wherein forming the first cover pattern and the second cover pattern comprises:
forming a cover layer inside the data storage layer; and
forming the first cover pattern and the second cover pattern by removing a segment of the cover layer located along a minor-axis of the channel opening.

11. The method of claim 1, further comprising forming the first data storage pattern and the second data storage pattern extending in the first direction.

12. The method of claim 1, further comprising forming the channel layer including a first angled region located at a first end of the first data storage pattern and a second angled region located at a second end of the second data storage pattern.

13. The method of claim 12, further comprising removing the first angled region and the second angled region from the channel layer when forming the first channel pattern and the second channel pattern.

14. The method of claim 1, further comprising, after the forming the first channel pattern and the second channel pattern:
removing the plurality of barrier patterns, resulting in formation of a shaped opening; and
filling the shaped opening with a core material layer.

15. The method of claim 1, further comprising forming a tunneling layer covering the first storage pattern and the second data storage pattern.

16. The method of claim 15, further comprising forming, in the tunneling layer, a first angled region at a first end of the first data storage pattern and a second angled region located at a second end of the second data storage pattern.

17. The method of claim 16, further comprising forming the channel layer extending along an inner surface of the tunneling layer.

18. The method of claim 16, further comprising exposing the first angled region and the second angled region of the tunneling layer when forming of the first channel pattern and the second channel pattern.
